(19) United States
(12) Patent Application Publication
(10) Pub. No.: US 2024/0145491 A1
(43) Pub. Date: May 2, 2024

(54) ARRAY SUBSTRATE, DISPLAY PANEL AND DISPLAY DEVICE

(71) Applicant: Wuhan Tianma Microelectronics Co., Ltd., Wuhan (CN)

(72) Inventors: Zihui YUAN, Wuhan (CN); Hongliang YU, Wuhan (CN)

(73) Assignee: Wuhan Tianma Microelectronics Co., Ltd., Wuhan (CN)

(21) Appl. No.: 18/405,228

(22) Filed: Jan. 5, 2024

(30) Foreign Application Priority Data
Mar. 31, 2023 (CN) 202310345680.X

(51) Int. Cl. H01L 27/12; H01L 25/075; H01L 25/16

(52) U.S. Cl. CPC H01L 27/1244; H01L 25/0753; H01L 25/167

(57) ABSTRACT

An array substrate includes a base substrate having a display region and a non-display region, the display region includes a corner display region and a middle display region; the display region includes a plurality of pixel circuits arranged in an array and a plurality of data signal lines, and a column of pixel circuits are electrically connected to at least two data signal lines; and further includes a plurality of first fan-out wires, where a first terminal of a first fan-out wire of the plurality of first fan-out wires is electrically connected to a data signal line located in the corner display region; the non-display region includes a fan-out region, and the fan-out region includes a plurality of second fan-out wires; a terminal of a second fan-out wire of part of the plurality of second fan-out wires is electrically connected to the second terminal of the first fan-out wire.

### CROSS-REFERENCE TO RELATED APPLICATION

This application claims priority to Chinese Patent Application No. 202310345680.X filed Mar. 31, 2023, the disclosure of which is incorporated herein by reference in its entirety.

### TECHNICAL FIELD

Embodiments of the present disclosure relate to the display technology and, for example, to an array substrate, a display panel and a display device.

### BACKGROUND

With the development of display technology, the screen-to-body ratio of the display panel has become increasingly large, and the narrow bezel technology has become increasingly popular. In the related art, the technique of laying out part of fan-out lines in the display region is adopted to achieve the narrow bezel of the product. In addition, with the improvement of the resolution of the display panel, to improve the stability of the circuit, the form of alternately writing signals into the pixel circuit is adopted to achieve the double data line (DDL) design so that the hop effect caused by each row of pixel switches on the same data signal line can be reduced, thereby improving the circuit stability.

However, the DDL design increases the number of data signal lines. Therefore, in the conventional design, the switched lines of a multiplexer circuit are added at the R corner below the display region. Since the multiplexer circuit occupies a certain space, the wiring space of the fan-out wires is compressed, and the bezel becomes large, thereby hardly achieving the narrow bezel design.

### SUMMARY

The embodiments of the present disclosure provide an array substrate, a display panel and a display device, and the array substrate can increase the effective display ratio and reduce the wiring space, thereby achieving an extremely narrow bezel.

In a first aspect, the embodiments of the present disclosure provide an array substrate. The array substrate includes a base substrate and a plurality of first fan-out wires.

The base substrate includes a display region and a non-display region. The display region includes a corner display region and a middle display region, and the corner display region is located between the middle display region and the non-display region.

The display region includes a plurality of pixel circuits arranged in an array and a plurality of data signal lines, the plurality of pixel circuits and the plurality of data signal lines are located on one side of the base substrate, and a column of pixel circuits of the plurality of pixel circuits are electrically connected to at least two of the plurality of data signal lines.

A first terminal of a first fan-out wire of the plurality of first fan-out wires is electrically connected to a data signal line located in the corner display region, and a second terminal of the first fan-out wire is located on one side, facing the middle display region, of the data signal line electrically connected to the first terminal of the first fan-out wire.

The non-display region includes a fan-out region, and the fan-out region includes a plurality of second fan-out wires.

A terminal of a second fan-out wire of part of the plurality of second fan-out wires is electrically connected to the second terminal of the first fan-out wire.

In a second aspect, the embodiments of the present disclosure further provide an array substrate. The array substrate includes a base substrate and a plurality of first fan-out wires.

The base substrate includes a display region and a non-display region. The display region includes a corner display region and a middle display region, and the corner display region is located between the middle display region and the non-display region.

The display region includes a plurality of pixel circuits arranged in an array and a plurality of data signal lines, the plurality of pixel circuits and the plurality of data signal lines are located on one side of the base substrate, and a column of pixel circuits are electrically connected to at least two data signal lines. A pixel circuit of the plurality of pixel circuits includes an N-type transistor and a P-type transistor, the N-type transistor includes a metal oxide active layer, and the P-type transistor includes a low-temperature polycrystalline silicon active layer.

The first terminal of a first fan-out wire of the plurality of first fan-out wires is electrically connected to a data signal line located in the corner display region, and a second terminal of the first fan-out wire is located on one side, facing the middle display region, of the data signal line electrically connected to the first terminal of the first fan-out wire.

The non-display region includes a fan-out region, and the fan-out region includes a plurality of second fan-out wires.

A terminal of a second fan-out wire of part of the plurality of second fan-out wires is electrically connected to the second terminal of the first fan-out wire.

The first fan-out wire and a gate layer of the N-type transistor are disposed in the same layer.

In a third aspect, the embodiments of the present disclosure further provide a display panel including the array substrate described above.

In a fourth aspect, the embodiments of the present disclosure further provide a display device including the display panel described above.

### BRIEF DESCRIPTION OF DRAWINGS

FIG. 1 is a structure diagram of an array substrate according to an embodiment of the present disclosure;

FIG. 2 is a partial structure diagram of an array substrate according to an embodiment of the present disclosure;

FIG. 3 is a structure diagram of a pixel circuit according to an embodiment of the present disclosure;

FIG. 4 is a partial structure diagram of an array substrate according to an embodiment of the present disclosure;

FIGS. 5 to 9 are exploded diagrams of film layers of the array substrate shown in FIG. 4;

FIG. 10 is a partial structure diagram of another array substrate according to an embodiment of the present disclosure;

FIG. 11 is a partial structure diagram of yet another array substrate according to an embodiment of the present disclosure;

FIG. 12 is a partial structure diagram of yet another array substrate according to an embodiment of the present disclosure;

FIG. 13 is a partial structure diagram of yet another array substrate according to an embodiment of the present disclosure;

FIG. 14 is a partial structure diagram of yet another array substrate according to an embodiment of the present disclosure;

FIG. 15 is a structure diagram of a first fan-out wire according to an embodiment of the present disclosure;

FIG. 16 is a sectional view of an array substrate according to an embodiment of the present disclosure;

FIG. 17 is a partial structure diagram of yet another array substrate according to an embodiment of the present disclosure;

FIG. 18 is a structure diagram of another pixel circuit according to an embodiment of the present disclosure;

FIG. 19 is a sectional view of another array substrate according to an embodiment of the present disclosure; and

FIG. 20 is a structure diagram of a display device according to an embodiment of the present disclosure.

### DETAILED DESCRIPTION

The present disclosure is further described in detail hereinafter in connection with drawings and embodiments. It is to be understood that the embodiments described herein are intended to illustrate and not to limit the present disclosure. Additionally, it is to be noted that to facilitate description, only part, not all, of structures related to the present disclosure are illustrated in the drawings.

The terminology used herein is for the purpose of describing particular embodiments only and is not intended to be limiting of the present disclosure. It is to be noted that spatially related terms such as “on”, “below”, “left” and “right” described in the embodiments of the present disclosure are described from the perspectives illustrated in the drawings and are not to be construed as a limitation to the embodiments of the present disclosure. Additionally, in the context, it is to be understood that when an element is formed “on” or “below” another element, the element may be directly formed “on” or “below” another element, or may be indirectly formed “on” or “below” another element via an intermediate element. The terms “first”, “second” and the like are merely used for the purpose of description and do not denote any order, quantity, or importance, but rather are used to distinguish different components. For those of ordinary skill in the art, specific meanings of the preceding terms in the present disclosure may be understood according to specific situations.

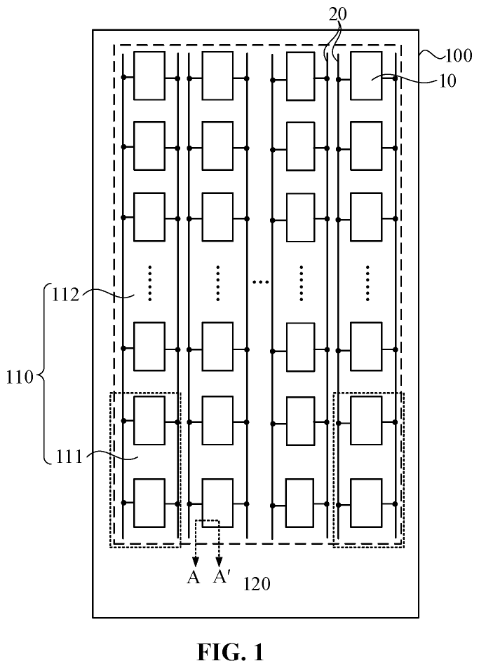

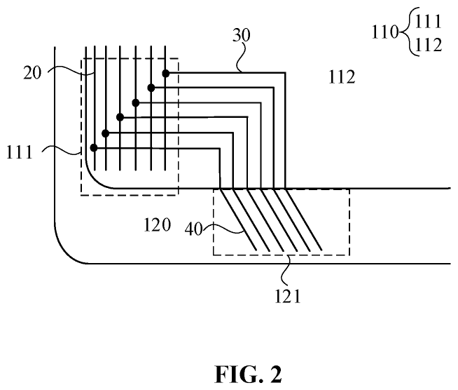

FIG. 1 is a structure diagram of an array substrate according to an embodiment of the present disclosure. With reference to FIG. 1, the array substrate includes a base substrate 100. The base substrate 100 includes a display region 110 and a non-display region 120. The display region 110 includes a corner display region 111 and a middle display region 112, and the corner display region 111 is located between the middle display region 112 and the non-display region 120. The display region 110 includes a plurality of pixel circuits 10 arranged in an array and a plurality of data signal lines 20, the plurality of pixel circuits 10 and the plurality of data signal lines 20 are located on one side of the base substrate 100, and a column of pixel circuits 10 are electrically connected to at least two (FIG. 1 illustrates two data signal lines, which is not intended to be limiting of the embodiments of the present disclosure) data signal lines 20. FIG. 2 is a partial structure diagram of an array substrate according to an embodiment of the present disclosure. With reference to FIG. 2, the array substrate further includes a plurality of first fan-out wires 30. A first terminal of a first fan-out wire 30 of the plurality of first fan-out wires 30 is electrically connected to a data signal line 20 located in the corner display region 111, and a second terminal of the first fan-out wire 30 is located on one side, facing the middle display region 112, of the data signal line 20 electrically connected to the first terminal of the first fan-out wire 30. The non-display region 120 includes a fan-out region 121, and the fan-out region 121 includes a plurality of second fan-out wires 40. A terminal of a second fan-out wire 40 of a part of the plurality of second fan-out wires 40 is electrically connected to the second terminal of the first fan-out wire 30.

The array substrate provided in this embodiment may be used in a display panel. The display panel herein may be an organic light-emitting diode (OLED) display panel or a micro light-emitting diode (Micro LED) display panel or may be other types of display panels, and the display panel using the array substrate is not limited to the embodiments of the present disclosure. The base substrate 100 may be a rigid substrate such as a glass substrate, or may be a flexible substrate such as a polyimide (PI) substrate, and the base substrate 100 may be selected according to the actual situation in the actual application. The display region 110 of the base substrate 100 includes a plurality of pixel circuits 10 arranged in an array, and the structure of each pixel circuit may be designed according to the actual situation, for example, the structure may be a 7T1C structure including seven transistors and one capacitor. For example, with reference to FIG. 1, the plurality of pixel circuits 10 are arranged in an array including a plurality of rows and a plurality of columns, and two data signal lines 20 are electrically connected to one column of pixel circuits 10 for alternately providing data signals for the one column of pixel circuits 10. The two data signal lines 20 are illustratively disposed on both sides of the one column of pixel circuits 10, which is not intended to be limiting of the embodiments of the present disclosure. Since FIG. 1 shows a top view of the array substrate, the positional relationship of film layers is not shown in FIG. 1.

It is to be understood that in the structure of the display panel, each of the four corners of the display region 110 is generally designed as a rounded corner and is commonly referred to as an “R-corner” region, that is, a corner display region 111, and the corner display region 111 is located between the middle display region 112 and the non-display region 120. Since an arc-shaped design exists in the corner display region 111, to improve the display quality, sub-pixels need to be disposed in a stepped form at the arc-shaped R corner to reduce the saw tooth-shaped distortion of the display picture, and the scan signal lines/data drive signal lines controlling such sub-pixels are arranged in the non-display region adjacent to the R corner due to space limitation. Signal lines controlling sub-pixels arranged in the R corner may occupy part of the space of the non-display region, resulting in a large proportion of the non-display region to the overall display device and making it difficult to achieve the narrow bezel effect. To ensure the narrow bezel effect of the display panel, the technique of laying out part of fan-out lines in the display region provided in this embodiment is adopted, that is, a data signal line 20 in the corner display region 111 is led to the middle display region 112 or a location close to the middle display region 112 through a first fan-out wire 30 to be connected to a second fan-out wire 40 in the fan-out region 121, thereby achieving the narrow bezel effect. With reference to FIG. 2, the second fan-out wires 40 in the fan-out region 121 may be used to be connected to a driver chip (which is not shown in FIG. 2). In this embodiment, one part of the second fan-out wires 40 are connected to first fan-out wires 30, and another part of the second fan-out wires 40 (which are not shown in FIG. 2) are directly connected to data signal lines 20 in the middle display region. By laying out the first fan-out wires 30 in the display region, the width of the non-display region 120 can be effectively reduced, thereby achieving the narrow bezel effect of the display panel.

In the solution of this embodiment of the present disclosure, a column of pixel circuits are set to be electrically connected to at least two data signal lines, and the at least two data signal lines alternately write signals into pixel circuits so that the hop effect caused by each row of pixel switches on the same data signal line can be reduced, thereby improving the circuit stability. The first fan-out wire is disposed in the corner display region, the first terminal of the first fan-out wire is electrically connected to the data line in the corner display region, and the second terminal of the first fan-out wire is connected to the second fan-out wire in the fan-out region so that the wiring layout where part of fan-out lines are disposed in the display region is achieved, thereby reducing the wiring space and achieving the narrow bezel effect.

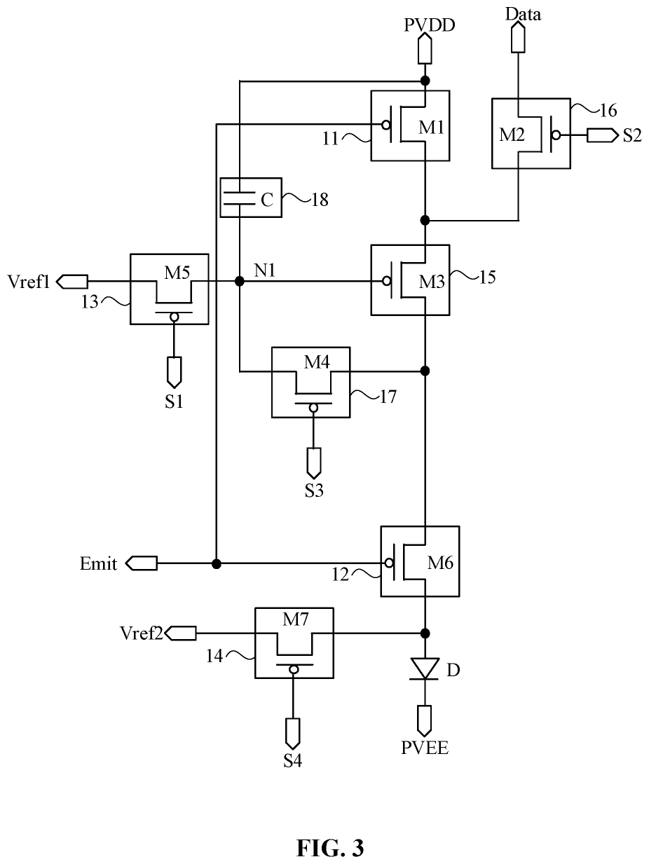

For example, FIG. 3 is a structure diagram of a pixel circuit according to an embodiment of the present disclosure. With reference to FIG. 3, in an embodiment, a pixel circuit 10 includes a first light emission control module 11, a second light emission control module 12, a first initialization module 13, a second initialization module 14, a drive module 15, a data write module 16, a threshold compensation module 17, and a storage module 18. A control terminal of the first light emission control module 11 is electrically connected to an enable signal line Emit, a first terminal of the first light emission control module 11 is electrically connected to a first power voltage signal line PVDD, and a second terminal of the first light emission control module 11 is electrically connected to a first terminal of the first drive module 15. A control terminal of the drive module 15 is electrically connected to a first node N1, and a second terminal of the drive module 15 is electrically connected to a first terminal of the second light emission control module 12. A control terminal of the second light emission control module 12 is electrically connected to the enable signal line Emit, and a second terminal of the second light emission control module 12 is electrically connected to a first electrode of a light-emitting element D. A control terminal of the first initialization module 13 is electrically connected to a first scan signal line S1, a first terminal of the first initialization module 13 is electrically connected to a first reference signal line Vref1, and a second terminal of the first initialization module 13 is electrically connected to the first node N1. A control terminal of the data write module 16 is electrically connected to a second scan signal line S2, a first terminal of the data write module 16 is electrically connected to the data signal line Data, and a second terminal of the data write module 16 is electrically connected to a first terminal of the drive module 15. A control terminal of the threshold compensation module 17 is electrically connected to a third scan signal line S3, a first terminal of the threshold compensation module 17 is electrically connected to the second terminal of the drive module 15, and a second terminal of the threshold compensation module 17 is electrically connected to the first node N1. A control terminal of the second initialization module 14 is electrically connected to a fourth scan signal line S4, a first terminal of the second initialization module 14 is electrically connected to a second reference signal line Vref2, and a second terminal of the second initialization module 14 is electrically connected to the first electrode of the light-emitting element D. A second electrode of the light-emitting element D is electrically connected to a second power voltage signal line PVEE. A first terminal of the storage module 18 is electrically connected to the first node N1, and a second terminal of the storage module 18 is electrically connected to the first power voltage signal line PVDD.

In an embodiment, with reference to FIG. 3, the pixel circuit is provided with a first light emission control module 11, a second light emission control module 12, a first initialization module 13, a second initialization module 14, a drive module 15, a data write module 16, a threshold compensation module 17, and a storage module 18. A control terminal of the first initialization module 13 is electrically connected to the first scan signal line S1, a first terminal of the first initialization module 13 is electrically connected to a first reference signal line Vref1, and a second terminal of the first initialization module 13 is electrically connected to the first node N1. In an initialization stage, the first initialization module 13 is on according to a first scan signal transmitted from the first scan signal line S1 and writes a first reference signal into the first node N1, the control terminal of the drive module 15 is electrically connected to the first node N1, and the first reference signal is written into the control terminal of the drive module 15 to complete the initialization of the drive module 15.

A control terminal of the data write module 16 is electrically connected to the second scan signal line S2, a first terminal of the data write module 16 is electrically connected to the data signal line Data, and a second terminal of the data write module 16 is electrically connected to a first terminal of the drive module 15. A control terminal of the threshold compensation module 17 is electrically connected to the third scan signal line S3, a first terminal of the threshold compensation module 17 is electrically connected to the second terminal of the drive module 15, and a second terminal of the threshold compensation module 17 is electrically connected to the first node N1. A first terminal of the storage module 18 is electrically connected to the first node N1, and a second terminal of the storage module 18 is electrically connected to the first power voltage signal line PVDD. In a data write stage, the data write module 16 is on according to a second scan signal transmitted from the second scan signal line S2, the threshold compensation module 17 is on according to a third scan signal transmitted from the third scan signal line S3, the drive module 15 is also on, a data voltage signal is written to the control terminal (that is, the first node N1) of the drive module 15 sequentially through the data write module 16, the drive module 15 and the threshold compensation module 17, and the memory module 18 stores the voltage of the first node N1.

A control terminal of the second initialization module 14 is electrically connected to the fourth scan signal line S4, a first terminal of the second initialization module 14 is electrically connected to the second reference signal line Vref2, and a second terminal of the second initialization module 14 is electrically connected to the first electrode of the light-emitting element D. In the data write stage, the second initialization module 14 is on according to a fourth scan signal transmitted from the fourth scan signal line S4 and writes a second reference signal into the first electrode of the light-emitting element D to initialize the first electrode of the light-emitting element D.

A control terminal of the first light emission control module 11 is electrically connected to the enable signal line Emit, a first terminal of the first light emission control module 11 is electrically connected to the first power voltage signal line PVDD, and a second terminal of the first light emission control module 11 is electrically connected to a first terminal of the first drive module 15. A second terminal of the drive module 15 is electrically connected to a first terminal of the second light emission control module 12. A control terminal of the second light emission control module 12 is electrically connected to the enable signal line Emit, and a second terminal of the second light emission control module 12 is electrically connected to the first electrode of the light-emitting element D. In the light emission stage, the first light emission control module 11 and the second light emission control module 12 are on according to an enable signal transmitted from the enable signal line Emit, the drive module 15 is on, and utilizing the first light emission control module 11, the drive module 15 and the second light emission control module 12, a power voltage signal generates a drive current to drive the light-emitting element D to emit light.

In an embodiment, the first light emission control module 11 includes a first transistor M1, the data write module 16 includes a second transistor M2, the drive module 15 includes a third transistor M3, the threshold compensation module 17 includes a fourth transistor M4, the first initialization module 13 includes a fifth transistor M5, the second light emission control module 12 includes a sixth transistor M6, the second initialization module 14 includes a seventh transistor M7, and the storage module 18 includes a storage capacitor C; the first electrode may be used as the cathode of the light-emitting element D.

FIG. 3 shows a schematic diagram of the connection structure of a 7T1C pixel circuit. The connection of the elements in the pixel circuit is optional, and in the actual application, those skilled in the art can adjust the design manner of the pixel circuit according to actual requirements. For example, in a certain embodiment, the first initialization module 13 may be electrically connected to the second terminal of the drive module 15, and at least two scan signal lines may be the same signal line. For example, the first scan signal line S1 and the fourth scan signal line S4 may be the same signal line, the second scan signal line S2 and the third scan signal line S3 may be the same signal line, and the first reference signal line Vref1 and the second reference signal line Vref2 may be the same signal line. The following embodiments are illustrated using the preceding connection of the elements in the 7T1C pixel circuit as an example and are not intended to be limiting of the embodiments of the present disclosure. The circuit structure shown in FIG. 3 is illustrated using an example where the transistors are all P-type transistors. In an embodiment, the transistors in the pixel circuit are all P-type transistors or N-type transistors. In the actual application, the type of the transistors may be designed according to the actual situation.

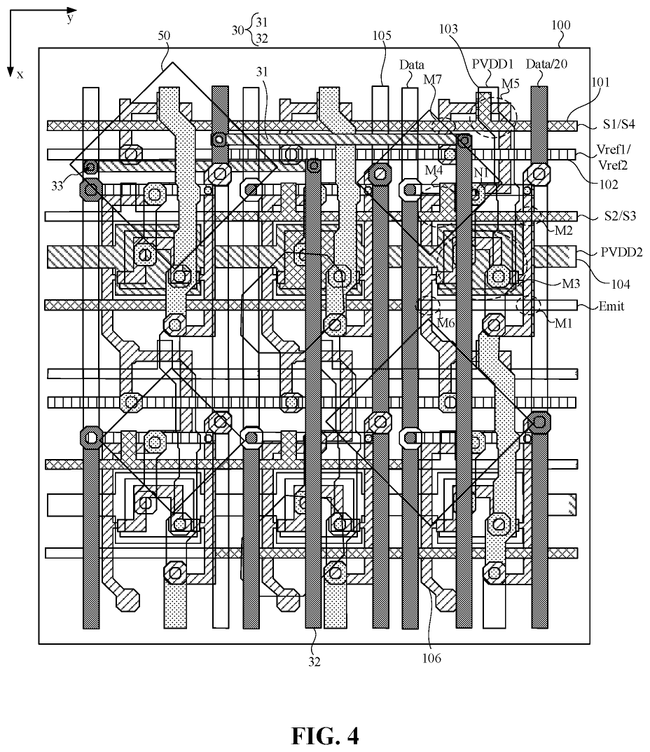

FIG. 4 is a partial structure diagram of an array substrate according to an embodiment of the present disclosure. With reference to FIG. 4, in an embodiment, the pixel circuit includes an active layer 106 and further includes a first metal layer 101, a second metal layer 102, a third metal layer 103, a fourth metal layer 104, and a fifth metal layer 105. The enable signal line Emit, the first scan signal line S1, the second scan signal line S2, the third scan signal line S3, and the fourth scan signal line S4 are located in the first metal layer 101. The first reference signal line Vref1 and the second reference signal line Vref2 are located in the second metal layer 102. The first power voltage signal line PVDD is located in the third metal layer 103 and the fourth metal layer 104. The data signal line Data (20) is located in the fifth metal layer 105. The first fan-out wire 30 is located in the fourth metal layer 104 and the fifth metal layer 105.

In an embodiment, the first power voltage signal line PVDD includes a first sub-power voltage signal line PVDD1 located in the third metal layer 103 and a second sub-power voltage signal line PVDD2 located in the fourth metal layer 104. The first sub-power voltage signal line PVDD1 extends in a first direction x, the second sub-power voltage signal line PVDD2 extends in a second direction y, and the first direction x intersects the second direction y. The first fan-out wire 30 includes a first wire 31 located in the fourth metal layer 104 and a second wire 32 located in the fifth metal layer 105, the first wire 31 extends in the second direction y, and the second wire 32 extends in the first direction x.

The first direction x is longitudinal, and the second direction y is lateral. The first wire 31 and the second sub-power voltage signal line PVDD2 are disposed in the same layer and extend in the same direction, and the second wire 32 and the data signal line 20 are disposed in the same layer and extend in the same direction, thereby avoiding the short circuit caused by the intersection of wires in the same layer. By disposing the first fan-out wire 30 inside the display region, the data signal lines in the corner region are hidden in the display region, thereby solving the problem that the non-display region needs to be occupied to set wires due to insufficient space of the corner display region and preventing the bezel from being too wide. In the actual application, the first wire 31 and the second wire 32 may also be designed with a plurality of bending structures to balance the wire resistance, and the specific wire shape may be designed according to the actual situation.

In an embodiment, the fourth metal layer 104 and the fifth metal layer 105 include an insulating layer (which is not shown in FIG. 4) therebetween, and the first wire 31 is electrically connected to the second wire 32 through a via 33 disposed in the insulating layer. The display region includes a plurality of light-emitting element disposition regions, and a light-emitting element disposition region of the plurality of light-emitting element disposition regions includes a metal electrode 50. The projection of the via 33 on the base substrate 100 is located in the projection of the metal electrode 50 on the base substrate 100.

The light-emitting element may be an OLED, and the metal electrode 50 may be the anode of the OLED. Since the anode is generally opaque, by setting the projection of the via 33 on the base substrate 100 to be in the projection of the metal electrode 50 on the base substrate 100, that is, by disposing the via 33 below the anode, the via 33 is prevented from being visible in the non-display state or at low brightness, and the display effect is prevented from being affected.

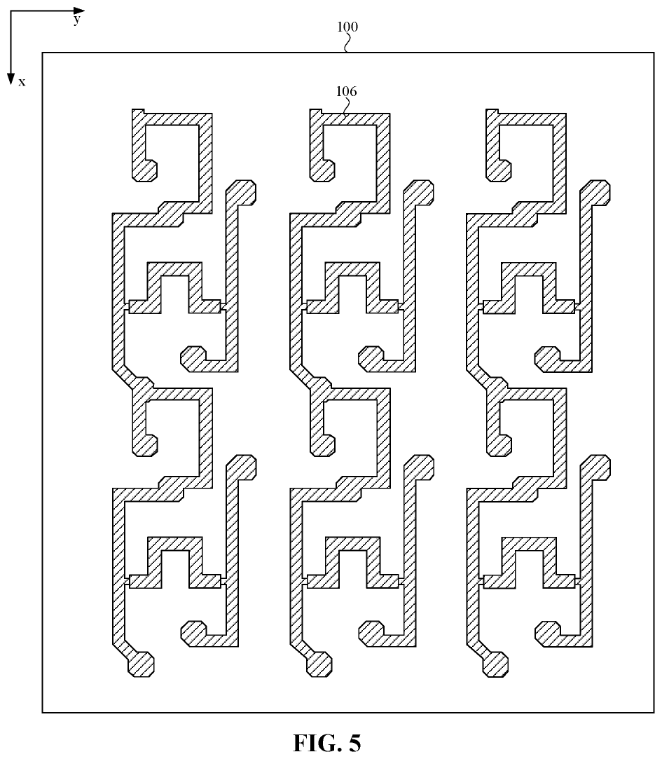

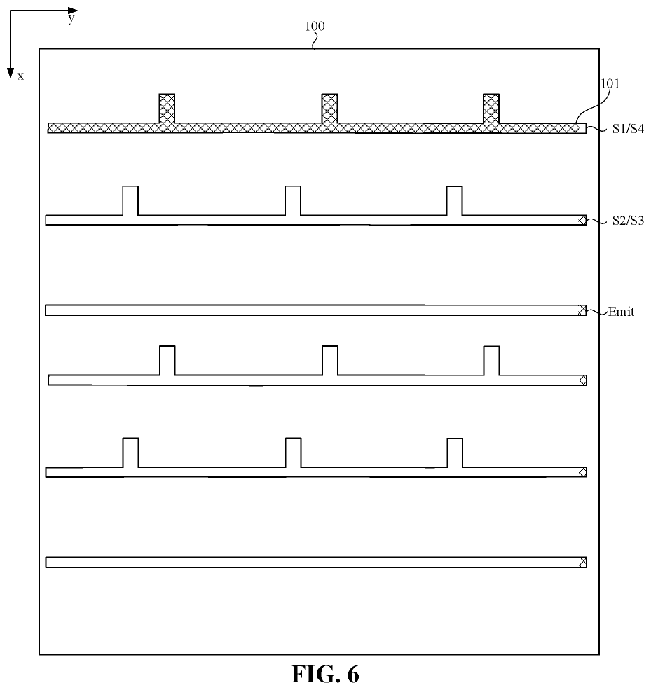

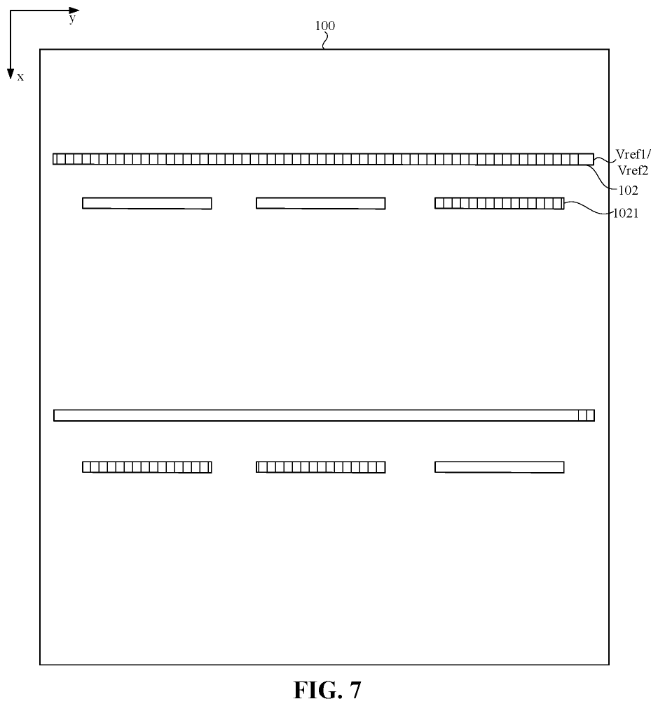

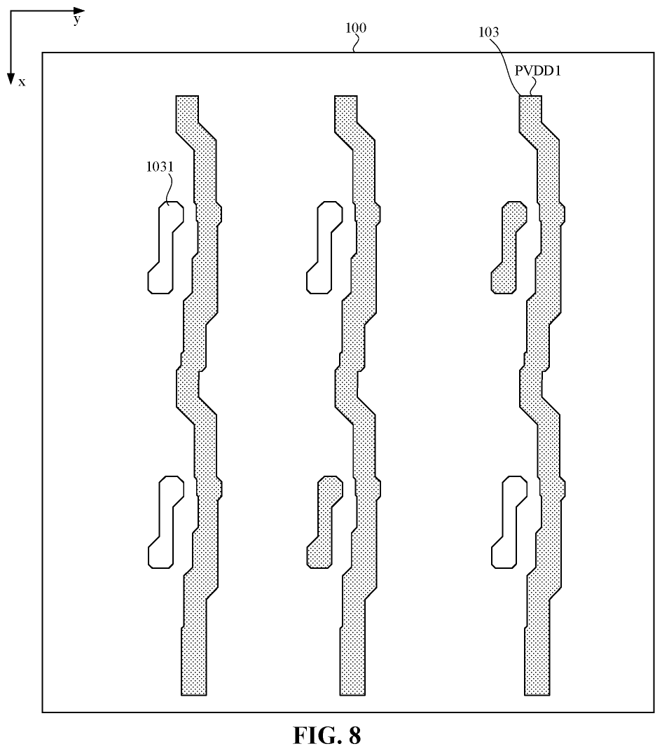

FIGS. 5 to 9 are exploded diagrams of film layers of the array substrate shown in FIG. 4. FIG. 5 shows the active layer. FIG. 6 shows the first metal layer 101. FIG. 7 shows the second metal layer 102, where the wire 1021 is a jumper line between a data line on the left side and the active layer 106. FIG. 8 shows the third metal layer 103, where the wire 1031 is a jumper wire in the pixel circuit. FIG. 9 shows the fourth metal layer 104 and the fifth metal layer. For simplicity, a direct connection hole of the metal layers is not shown in FIGS. 5 to 8, and FIG. 9 shows a connection hole between the fourth metal layer 104 and the fifth metal layer 105.

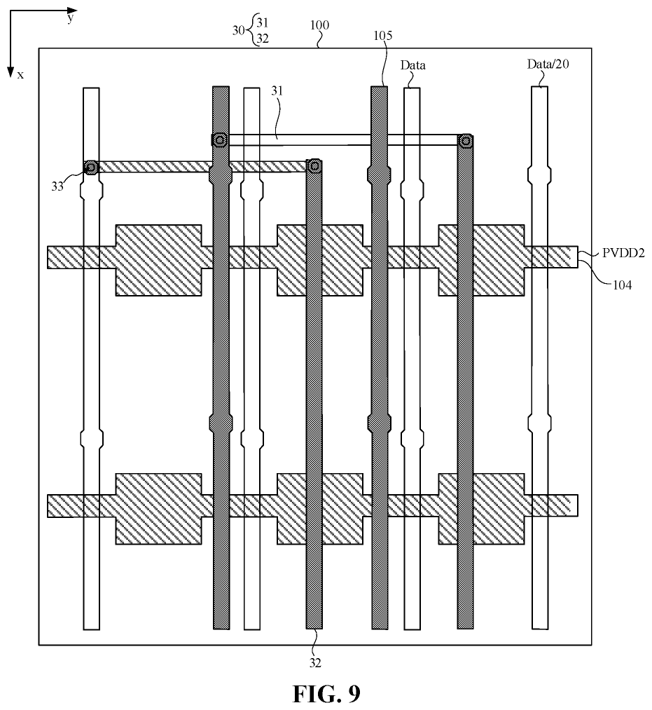

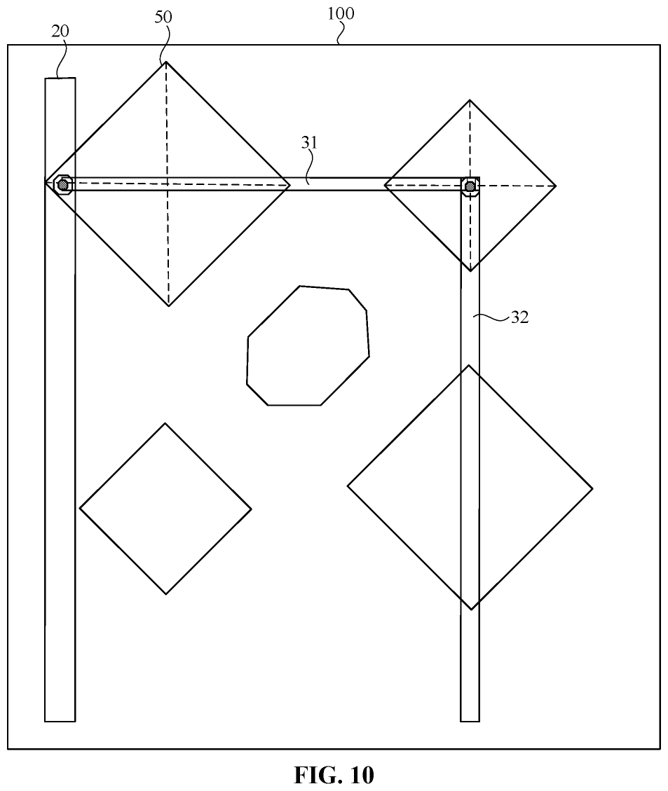

FIG. 10 is a partial structure diagram of another array substrate according to an embodiment of the present disclosure. With reference to FIG. 10, in an embodiment, the display region includes a plurality of light-emitting element disposition regions, and a light-emitting element disposition region of the plurality of light-emitting element disposition regions includes a metal electrode 50. The projection of a center of the metal electrode 50 on the base substrate 100 overlaps the projection of the first wire 31 on the base substrate. By setting the first wire 31 to pass through the center of the metal electrode 50, the pixel flatness is optimized, and the color cast is reduced.

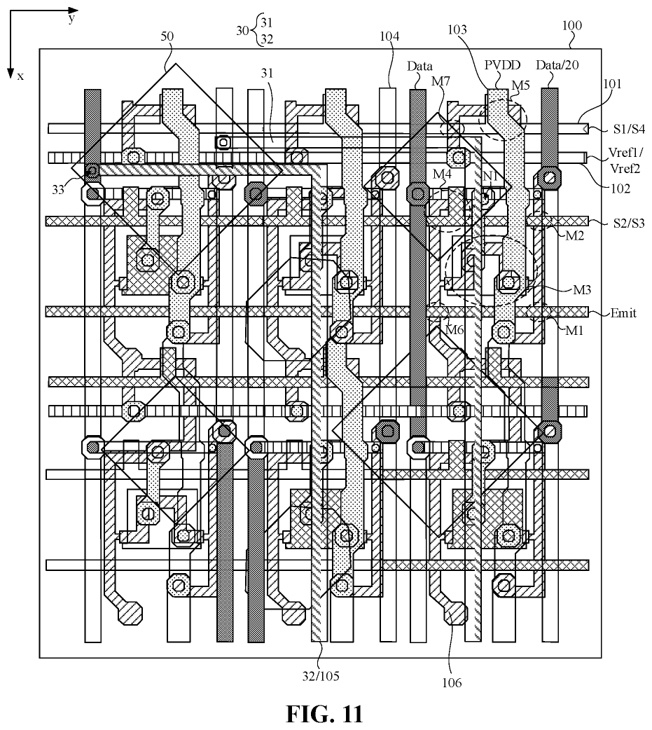

FIG. 11 is a partial structure diagram of yet another array substrate according to an embodiment of the present disclosure. With reference to FIG. 11, in an embodiment, the pixel circuit includes a first metal layer 101, a second metal layer 102, a third metal layer 103, a fourth metal layer 104, and a fifth metal layer 105. The enable signal line Emit, the first scan signal line S1, the second scan signal line S2, the third scan signal line S3, and the fourth scan signal line S4 are located in the first metal layer 101. The first reference signal line Vref2 and the second reference signal line Vref2 are located in the second metal layer 102. The first power voltage signal line PVDD is located in the third metal layer 103. The data signal line Data (20) is located in the fourth metal layer 104. The first fan-out wire 30 is located in the fifth metal layer 105.

Different from the previous embodiment, the first power voltage signal line PVDD in this embodiment is designed to be a one-layer wire, the first wire 31 and the second wire 32 in the first fan-out wire 30 are located only in the fifth metal layer 105, and the two data signal lines 20 are electrically connected to the first fan-out wire 30 through reserved line switching holes.

In an embodiment, with continued reference to FIG. 11, the first fan-out wire includes a first wire 31 extending in a second direction y and a second wire 32 extending in a first direction x, the first direction x is the same as the extending direction of the data signal line 20, and the first direction x intersects the second direction y. Since the fifth metal layer 105 is only designed with the first fan-out wire 30, the wires may be disposed in the lateral direction and the longitudinal direction simultaneously, thereby simplifying the design difficulty.

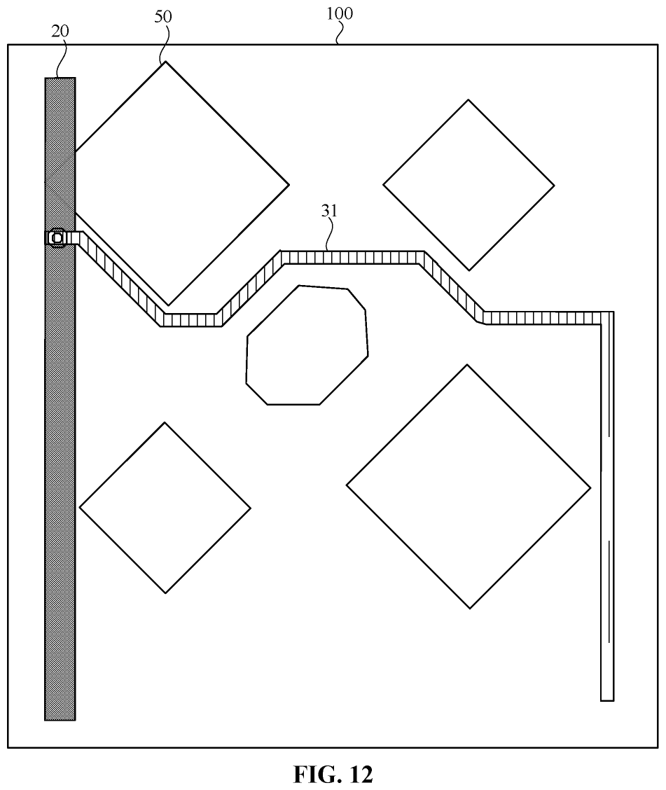

FIG. 12 is a partial structure diagram of yet another array substrate according to an embodiment of the present disclosure. With reference to FIG. 12, in an embodiment, the display region includes a plurality of light-emitting element disposition regions, and a light-emitting element disposition region of the plurality of light-emitting element disposition regions includes a metal electrode 50. The projection of the first wire 31 on the base substrate 100 includes a plurality of bending shapes, and the projection of the first wire 30 on the base substrate 100 does not overlap the projection of the metal electrode 50 on the base substrate 100.

The light-emitting element may be an OLED, and the metal electrode 50 may be the anode of the OLED. By setting the first wire 31 to bypass the metal electrode 50, that is, by setting the first wire 31 to bypass the opening of the light-emitting element, the pixel flatness can be optimized, and the color cast can be reduced.

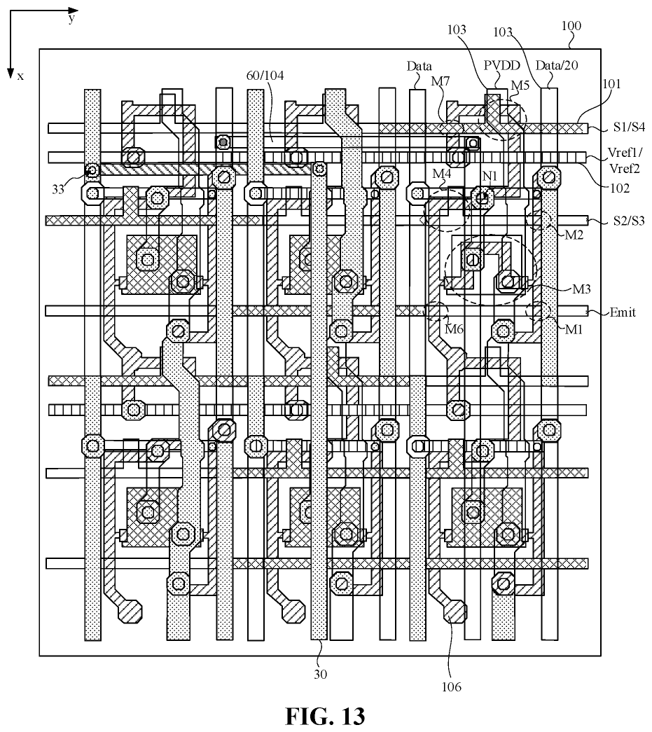

FIG. 13 is a partial structure diagram of yet another array substrate according to an embodiment of the present disclosure. With reference to FIG. 13, in an embodiment, the pixel circuit includes a first metal layer 101, a second metal layer 102, a third metal layer 103, and a fourth metal layer 104. The enable signal line Emit, the first scan signal line S1, the second scan signal line S2, the third scan signal line S3, the fourth scan signal line S4, and a first plate C1 of a storage capacitor C are located in the first metal layer 101. The first reference signal line Vref1, the second reference signal line Vref2, and a second plate C2 of the storage capacitor C are located in the second metal layer 102. The first power voltage signal line PVDD, the data signal line 20, and the first fan-out wire 30 are located in the third metal layer 103. The data signal line 20 is connected to the first fan-out wire 30 through a jumper signal line 60, and the jumper signal line 60 is located in the fourth metal layer 106.

In this embodiment, the first power voltage signal line PVDD, the data signal line 20 and the first fan-out wire 30 extend in the same direction and thus may be disposed in the same layer. The jumper signal line 60 is disposed to achieve the connection between the data signal line 20 and the first fan-out wire 30, and the jumper signal line 60 and the first fan-out wire 30 form the connection wire for connecting the signal data line 20 and a corresponding second fan-out wire 40 in the display region, thereby reducing the bezel. Moreover, compared with the related art, in this embodiment, no other film layers are added, thereby simplifying the process and reducing the cost.

In an embodiment, the display region includes a plurality of light-emitting element disposition regions, and a light-emitting element disposition region of the plurality of light-emitting element disposition regions includes a metal electrode. The projection of the jumper signal line on the base substrate does not overlap the projection of the metal electrode on the base substrate, or a projection of the jumper signal line on the base substrate overlaps the center of the projection of the metal electrode on the base substrate.

It is to be understood that similar to the preceding embodiments, by setting the projection of the jumper signal line on the base substrate not to overlap the projection of the metal electrode on the base substrate, that is, by setting the jumper signal line to bypass the opening where the light-emitting element is located, or by setting the projection of the jumper signal line on the base substrate to overlap the center of the projection of the metal electrode on the base substrate, the pixel flatness can be optimized, and the color cast can be reduced.

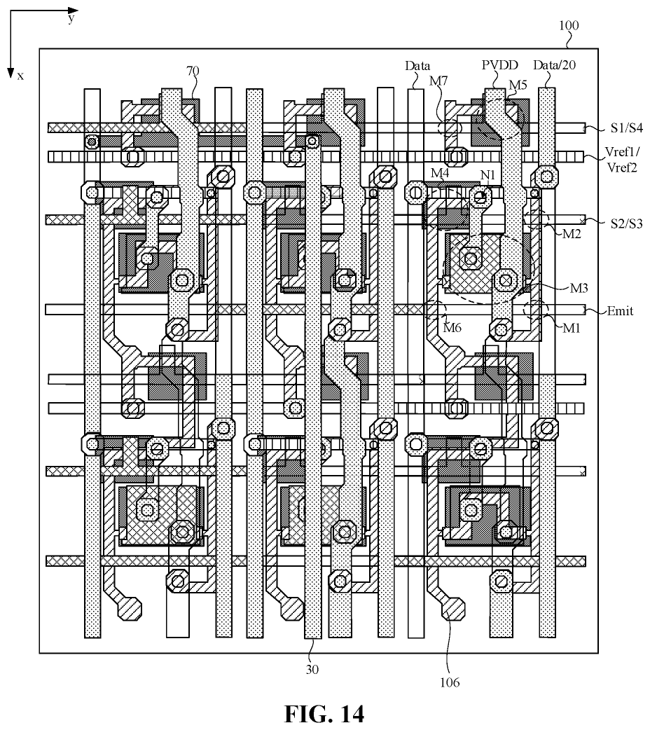

FIG. 14 is a partial structure diagram of yet another array substrate according to an embodiment of the present disclosure. With reference to FIG. 14, in an embodiment, the pixel circuit includes a plurality of transistors M1 to M7. A light-shielding metal layer 70 is located on one side of the base substrate 100 facing the pixel circuit, and in a direction perpendicular to the base substrate 100, the light-shielding metal layer 70 covers an active region of at least one of the plurality of transistors. At least part of the region of the first fan-out wire 30 and the light-shielding metal layer 70 are disposed in the same layer.

The light-shielding metal layer 70 is located below the pixel circuit for shading the active regions of part of the transistors. In this manner, the performance of the transistor can be improved. For example, the light-shielding metal layer 70 shields the drive transistor, thereby improving the stability of the threshold and subthreshold swing of the drive transistor, improving the anti-static interference capability of the array substrate, and protecting the key devices. In this embodiment, by reusing the light-shielding metal layer 70 to form the first fan-out wire 30, the requirements of the product can be met without adding masks, and the cost can be greatly reduced. Moreover, the light-shielding metal layer 70 is located below the pixel circuit, preventing the display uniformity from being affected.

With continued reference to FIG. 14, in an embodiment, the light-shielding metal layer 70 includes a plurality of light-shielding blocks, and in the direction of perpendicular to the base substrate 100, a light-shielding block of the plurality of light-shielding blocks covers an active region of at least one of the plurality of transistors (for example, in FIG. 14, the light-shielding block covers active layers of transistors M3, M4 and M5, which is not intended to be limiting of the embodiments of the present disclosure). The first fan-out wire 30 is electrically connected to at least one of the plurality of light-shielding blocks.

By setting the first fan-out wire 30 to be electrically connected to the at least one light-shielding block, the resistance of the first fan-out wire 30 can be effectively reduced, thereby preventing the wire resistance from greatly affecting the display performance.

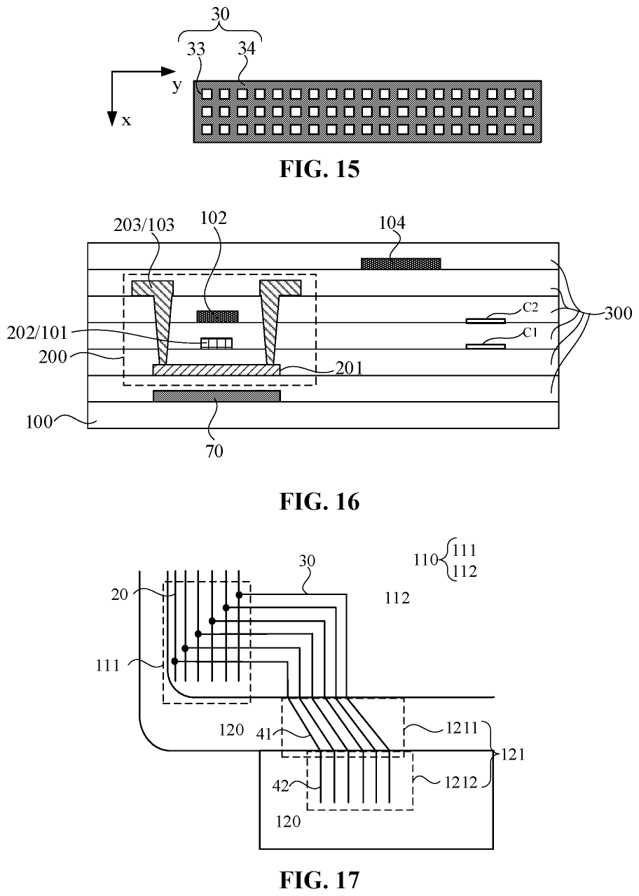

FIG. 15 is a structure diagram of a first fan-out wire according to an embodiment of the present disclosure. With reference to FIG. 15, in an embodiment, the first fan-out wire 30 includes a plurality of third wires 33 extending in a first direction x and a plurality of fourth wires 34 extending in a second direction y, the plurality of third wires 33 are electrically connected to the plurality of fourth wires 34 to form a mesh structure, and the first direction x intersects the second direction y.

Since the light-shielding metal layer 70 is located at one side of the pixel circuit facing the base substrate 100 (e.g., below the pixel circuit) and is not electrically connected to other metal layers in the pixel circuit, to reduce the resistance of the first fan-out wire 30, the first fan-out wires 30 may be designed as a mesh structure. In the actual application, the first direction x may be designed to be parallel to the column direction of the pixel circuit array, and the second direction y may be designed to be parallel to the row direction of the pixel circuit array. In other embodiments, the first direction x and the second direction y may be designed according to the actual situation. In the actual application, the design may be produced according to the actual situation.

In an embodiment, with continued reference to FIG. 14, the first light emission control module 11 includes a first transistor M1, the data write module 16 includes a second transistor M2, the drive module 15 includes a third transistor M3, the threshold compensation module 17 includes a fourth transistor M4, the first initialization module 13 includes a fifth transistor M5, the second light emission control module 12 includes a sixth transistor M6, the second initialization module 14 includes a seventh transistor M7, and the storage module 18 includes a storage capacitor C. In the direction perpendicular to the base substrate 100, the light-shielding metal layer 70 covers an active region of the third transistor M3, an active region of the fourth transistor M4, and an active region of the fifth transistor M5.

By setting the light-shielding metal layer 70 to shield the transistors M3/M4/M5 of the 7T1C pixel circuit, the signal stability of the first node N1 can be improved, the uniformity of the threshold and subthreshold swing of the third transistor M3 can be improved, and the whole copper rod friction test capability and the flat-panel electrostatic discharge (ESD) capability can be improved, thereby protecting the key devices.

FIG. 16 is a sectional view taken along the section line AA′ in FIG. 1. With reference to FIG. 16, in an embodiment, the pixel circuit includes a first metal layer 101, a second metal layer 102, a third metal layer 103, and a fourth metal layer 104. The enable signal line, the first scan signal line, the second scan signal line, the third scan signal line, the fourth scan signal line, and a first plate C1 of the storage capacitor are located in the first metal layer 101 (no signal line is specifically shown in FIG. 16). The first reference signal line, the second reference signal line, and a second plate C2 of the storage capacitor are located in the second metal layer 102. The data signal line is located in the third metal layer 103. The first power voltage signal line is located in the third metal layer 103 and the fourth metal layer 104.

In the actual application, an insulating layer 300 is disposed between two adjacent metal layers or between a metal layer and an active layer. The insulating layer 300 may be an inorganic insulating layer or an organic insulating layer and may be designed according to the actual situation in the actual application. When the wires in the different metal layers need to be connected to each other, the electrical connection between the wires may be achieved through a via disposed in the insulating layer, and when the wires in the same layer do not need to be electrically connected to each other, the technique of line switching may be adopted to avoid wire intersection. FIG. 16 illustrates one transistor 200. The transistor 200 includes an active layer 201, a gate layer 202 and a source and drain layer 203, the gate layer 202 is located in the first metal layer 101, and the source and drain layer 203 is located in the third metal layer 103.

In the embodiments of the present disclosure, the array substrate may further include other conventional film layers such as the light-emitting layer, a planarization layer and a pixel defining layer. The setting manner of the above-mentioned conventional film layers may be set by those skilled in the art according to actual requirements, and the setting manner is not limited to the embodiments of the present disclosure.

FIG. 17 is a partial structure diagram of yet another array substrate according to an embodiment of the present disclosure. With reference to FIG. 17, in an embodiment, the fan-out region 121 includes a first fan-out region 1211 and a second fan-out region 1212, and the first fan-out region 1211 is located on one side of the second fan-out region 1212 facing the display region 110. The first fan-out region 1211 includes a first sub-fan-out wire 41, the second fan-out region 1212 includes a second sub-fan-out wire 42, the first sub-fan-out wire 41 is located in the second metal layer and/or the third metal layer, and the second sub-fan-out wire 42 is located in the fourth metal layer.

In this embodiment, the line switching of data signal lines is achieved in the display region through the metal wires disposed in the same layer as the light-shielding metal layer. The data lines are wired to the first fan-out region 1211, switched through the second metal layer and/or the third metal layer to avoid the intersection of different signal lines in the same layer, then wired to the second fan-out region 1212, and switched to the fourth metal layer. In an embodiment, the second fan-out region 1212 is a bending region. By setting the second fan-out region 1212 to be a bending region, the bending of part of the non-display region can be achieved, thereby reducing the width of the bezel and achieving the narrow bezel effect. Moreover, the fourth metal layer generally adopts a structure stacked with a plurality of layers of metal and thus has a good bending performance, thereby preventing wires from being broken during bending.

In an embodiment, the transistors in the pixel circuit are all P-type transistors or N-type transistors. The transistors may be selected according to the actual situation in the actual application.

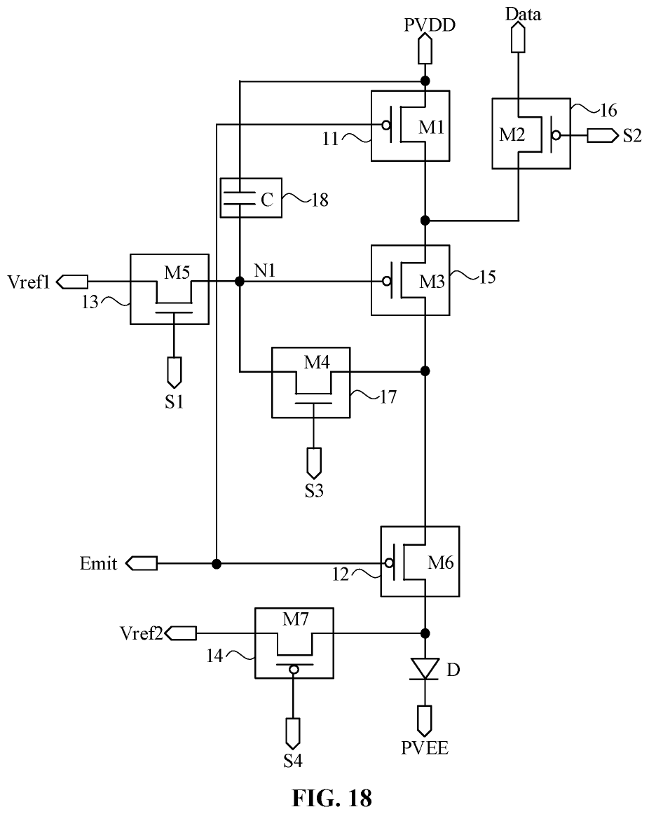

In the design of the pixel circuit, the pixel circuit may be formed using the same type of transistors, and the pixel circuit may also be formed using two types of transistors, that is, the pixel circuit includes both P-type transistors and N-type transistors. For example, FIG. 18 is a structure diagram of another pixel circuit according to an embodiment of the present disclosure. Different from FIG. 3, in this embodiment, the fourth transistor M4 and the fifth transistor M5 are N-type transistors, and the other transistors are P-type transistors, where the N-type transistor is a metal oxide (for example, indium gallium zinc oxide (IGZO)) transistor, and the P-type transistor is a low-temperature polycrystalline silicon transistor. The metal oxide transistor has the advantages of high transmittance, low electron mobility, large switch ratio and low power consumption, compared with the low-temperature polycrystalline silicon transistor, and the pixel circuit formed with the two types of transistors has better performance.

Based on this, the embodiments of the present disclosure further provide an array substrate. The array substrate includes a base substrate and a plurality of first fan-out wires. The base substrate includes a display region and a non-display region. The display region includes a corner display region and a middle display region, and the corner display region is located between the middle display region and the non-display region. The display region includes a plurality of pixel circuits arranged in an array and a plurality of data signal lines, the plurality of pixel circuits and the plurality of data signal lines are located on one side of the base substrate, and a column of pixel circuits are electrically connected to at least two data signal lines. A pixel circuit of the plurality of pixel circuits includes an N-type transistor and a P-type transistor, the N-type transistor includes a metal oxide active layer, and the P-type transistor includes a low-temperature polycrystalline silicon active layer. A first terminal of a first fan-out wire of the plurality of first fan-out wires is electrically connected to a data signal line located in the corner display region, and a second terminal of the first fan-out wire is located on one side, facing the middle display region, of the data signal line electrically connected to the first terminal of the first fan-out wire. The non-display region includes a fan-out region, and the fan-out region includes a plurality of second fan-out wires. A terminal of a second fan-out wire of part of the plurality of second fan-out wires is electrically connected to the second terminal of the first fan-out wire. The first fan-out wire and the gate layer of the N-type transistor are disposed in the same layer.

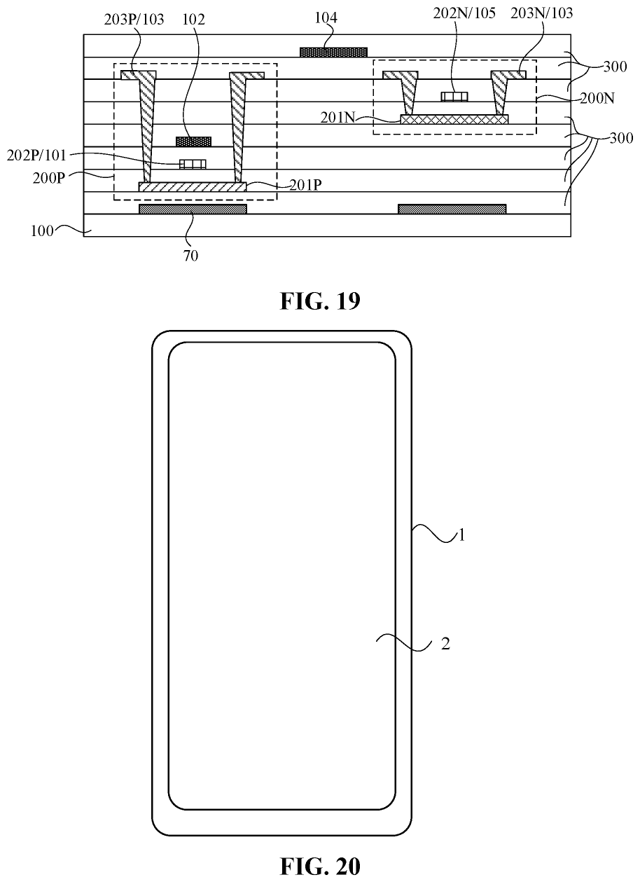

The setting manner of the first fan-out wire in this embodiment is similar to the setting manner in the preceding embodiments, and FIG. 19 is another sectional view taken along the section line AA′ in FIG. 1. With reference to FIG. 19, the array substrate includes an N-type transistor 200N and a P-type transistor 200P. The P-type transistor includes a first active layer 201P, a first gate layer 202P, and a first source and drain layer 203P, and the N-type transistor includes a second active layer 201N, a second gate layer 202N, and a second source and drain layer 203N, where the first fan-out wire and the gate layer of the N-type transistor are disposed in the same layer.

With continued reference to FIG. 19, in an embodiment, the array substrate further includes a light-shielding metal layer 70. The light-shielding metal layer 70 is located on one side of the base substrate 100 facing the pixel circuit, and in a direction perpendicular to the base substrate 100, the light-shielding metal layer 70 covers the active region of at least one of the N-type transistor or the P-type transistor.

In the actual application, the setting manner of the light-shielding metal layer 70 is similar to the setting manner in the preceding embodiments, and the light-shielding metal layer 70 may also cover the third transistor M3, the fourth transistor M4, and the fifth transistor M5. An insulating layer 300 is disposed between two adjacent metal layers or between a metal layer and an active layer. The insulating layer 300 may be an inorganic insulating layer or an organic insulating layer and may be designed according to the actual situation in the actual application.

The embodiments of the present disclosure further provide a display panel. The display panel includes any one of the array substrates provided in the embodiments described above. Since the display panel provided in this embodiment of the present disclosure includes any one of the array substrates provided in the embodiments described above, the display panel has the same or corresponding technical effects as the array substrates. The details are not repeated here.

FIG. 20 is a structure diagram of a display device according to an embodiment of the present disclosure. With reference to FIG. 20, the display device 1 includes the display panel 2 provided in the embodiments of the present disclosure. The display device 1 may specifically be a mobile phone, a computer, an intelligent wearable device, etc.

It is to be noted that the above are only preferred embodiments of the present disclosure and the principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure has been described in detail through the preceding embodiments, the present disclosure is not limited to the preceding embodiments and may include more equivalent embodiments without departing from the concept of the present disclosure. The scope of the present disclosure is determined by the scope of the appended claims.

What is claimed is:

1. An array substrate, comprising: a base substrate and a plurality of first fan-out wires, wherein,
the base substrate comprises a display region and a non-display region, and the display region comprises a corner display region and a middle display region; the corner display region is located between the middle display region and the non-display region; and the display region comprises a plurality of pixel circuits arranged in an array and a plurality of data signal lines, the plurality of pixel circuits and the plurality of data signal lines are located on one side of the base substrate, and a column of pixel circuits of the plurality of pixel circuits are electrically connected to at least two of the plurality of data signal lines;
a first terminal of a first fan-out wire of the plurality of first fan-out wires is electrically connected to a data signal line located in the corner display region, and a second terminal of the first fan-out wire is located on one side, facing the middle display region, of the data signal line electrically connected to the first terminal of the first fan-out wire; and
the non-display region comprises a fan-out region, the fan-out region comprises a plurality of second fan-out wires, and a terminal of a second fan-out wire of part of the plurality of second fan-out wires is electrically connected to the second terminal of the first fan-out wire.

2. The array substrate of claim 1, wherein a pixel circuit of the plurality of pixel circuits comprises a first light emission control module, a second light emission control module, a first initialization module, a second initialization module, a drive module, a data write module, a threshold compensation module, and a storage module;
a control terminal of the first light emission control module is electrically connected to an enable signal line, a first terminal of the first light emission control module is electrically connected to a first power voltage signal line, and a second terminal of the first light emission control module is electrically connected to a first terminal of the first drive module;
a control terminal of the drive module is electrically connected to a first node, and a second terminal of the drive module is electrically connected to a first terminal of the second light emission control module;
a control terminal of the second light emission control module is electrically connected to the enable signal line, and a second terminal of the second light emission control module is electrically connected to a first electrode of a light-emitting element;
a control terminal of the first initialization module is electrically connected to a first scan signal line, a first terminal of the first initialization module is electrically connected to a first reference signal line, and a second terminal of the first initialization module is electrically connected to the first node;
a control terminal of the data write module is electrically connected to a second scan signal line, a first terminal of the data write module is electrically connected to the data signal line, and a second terminal of the data write module is electrically connected to a first terminal of the drive module;
a control terminal of the threshold compensation module is electrically connected to a third scan signal line, a first terminal of the threshold compensation module is electrically connected to the second terminal of the drive module, and a second terminal of the threshold compensation module is electrically connected to the first node;
a control terminal of the second initialization module is electrically connected to a fourth scan signal line, a first terminal of the second initialization module is electrically connected to a second reference signal line, and a second terminal of the second initialization module is electrically connected to the first electrode of the light-emitting element; and
a first terminal of the storage module is electrically connected to the first node, and a second terminal of the storage module is electrically connected to the first power voltage signal line.

3. The array substrate of claim 2, wherein the pixel circuit comprises a first metal layer, a second metal layer, a third metal layer, a fourth metal layer, and a fifth metal layer;
the enable signal line, the first scan signal line, the second scan signal line, the third scan signal line, and the fourth scan signal line are located in the first metal layer;
the first reference signal line and the second reference signal line are located in the second metal layer;
the first power voltage signal line is located in the third metal layer and the fourth metal layer;
the data signal line is located in the fifth metal layer; and
the first fan-out wire is located in the fourth metal layer and the fifth metal layer.

4. The array substrate of claim 3, wherein the first power voltage signal line comprises a first sub-power voltage signal line located in the third metal layer and a second sub-power voltage signal line located in the fourth metal layer, the first sub-power voltage signal line extends in a first direction, the second sub-power voltage signal line extends in a second direction, and the first direction intersects the second direction; and
the first fan-out wire comprises a first wire located in the fourth metal layer and a second wire located in the fifth metal layer, the first wire extends in the second direction, and the second wire extends in the first direction.

5. The array substrate of claim 4, further comprising an insulating layer located between the fourth metal layer and the fifth metal layer and the first wire is electrically connected to the second wire through a via disposed in the insulating layer; wherein,
the display region comprises a plurality of light-emitting element disposition regions, and a light-emitting element disposition region of the plurality of light-emitting element disposition regions comprises a metal electrode; and
a projection of the via on the base substrate is located in a projection of the metal electrode on the base substrate.

6. The array substrate of claim 4, wherein the display region comprises a plurality of light-emitting element disposition regions, and a light-emitting element disposition region of the plurality of light-emitting element disposition regions comprises a metal electrode; and
a projection of a center of the metal electrode on the base substrate overlaps a projection of the first wire on the base substrate.

7. The array substrate of claim 2, wherein the pixel circuit comprises a first metal layer, a second metal layer, a third metal layer, a fourth metal layer, and a fifth metal layer;
the enable signal line, the first scan signal line, the second scan signal line, the third scan signal line, and the fourth scan signal line are located in the first metal layer;
the first reference signal line and the second reference signal line are located in the second metal layer;
the first power voltage signal line is located in the third metal layer;
the data signal line is located in the fourth metal layer; and
the first fan-out wire is located in the fifth metal layer.

8. The array substrate of claim 7, wherein the first fan-out wire comprises a first wire extending in a second direction and a second wire extending in a first direction, the first direction is the same as an extending direction of the data signal line, and the first direction intersects the second direction.

9. The array substrate of claim 8, wherein the display region comprises a plurality of light-emitting element disposition regions, and a light-emitting element disposition region of the plurality of light-emitting element disposition regions comprises a metal electrode; and
a projection of the first wire on the base substrate comprises a plurality of bending shapes and does not overlap a projection of the metal electrode on the base substrate.

10. The array substrate of claim 2, wherein the pixel circuit comprises a first metal layer, a second metal layer, a third metal layer, and a fourth metal layer, and the storage module comprises a storage capacitor;
the enable signal line, the first scan signal line, the second scan signal line, the third scan signal line, the fourth scan signal line, and a first plate of the storage capacitor are located in the first metal layer;
the first reference signal line, the second reference signal line, and a second plate of the storage capacitor are located in the second metal layer;
the first power voltage signal line, the data signal line, and the first fan-out wire are located in the third metal layer; and
the data signal line is connected to the first fan-out wire through a jumper signal line located in the fourth metal layer.

11. The array substrate of claim 10, wherein the display region comprises a plurality of light-emitting element disposition regions, and a light-emitting element disposition region of the plurality of light-emitting element disposition regions comprises a metal electrode; and
a projection of the jumper signal line on the base substrate does not overlap a projection of the metal electrode on the base substrate, or a projection of the jumper signal line on the base substrate overlaps a center of a projection of the metal electrode on the base substrate.

12. The array substrate of claim 2, wherein the pixel circuit comprises a plurality of transistors; and the array substrate further comprises a light-shielding metal layer, wherein,
the light-shielding metal layer is located on one side of the base substrate facing the pixel circuit, and covers an active region of at least one of the plurality of transistors in a direction perpendicular to the base substrate; and
at least part of the first fan-out wire and the light-shielding metal layer are disposed in a same layer.

13. The array substrate of claim 12, wherein the light-shielding metal layer comprises a plurality of light-shielding blocks, and in the direction of perpendicular to the base substrate, a light-shielding block of the plurality of light-shielding blocks covers an active region of at least one of the plurality of transistors; and
the first fan-out wire is electrically connected to at least one of the plurality of light-shielding blocks.

14. The array substrate of claim 12, wherein the first light emission control module comprises a first transistor, the data write module comprises a second transistor, the drive module comprises a third transistor, the threshold compensation module comprises a fourth transistor, the first initialization module comprises a fifth transistor, the second light emission control module comprises a sixth transistor, the second initialization module comprises a seventh transistor, and the storage module comprises a storage capacitor; and
in the direction perpendicular to the base substrate, the light-shielding metal layer covers an active region of the third transistor, an active region of the fourth transistor, and an active region of the fifth transistor.

15. The array substrate of claim 14, wherein the pixel circuit comprises a first metal layer, a second metal layer, a third metal layer, and a fourth metal layer;
the enable signal line, the first scan signal line, the second scan signal line, the third scan signal line, the fourth scan signal line, and a first plate of the storage capacitor are located in the first metal layer;
the first reference signal line, the second reference signal line, and a second plate of the storage capacitor are located in the second metal layer;
the data signal line is located in the third metal layer; and
the first power voltage signal line is located in the third metal layer and the fourth metal layer.

16. The array substrate of claim 15, wherein the fan-out region comprises a first fan-out region and a second fan-out region, and the first fan-out region is located on one side of the second fan-out region facing the display region; and
the first fan-out region comprises a first sub-fan-out wire, the second fan-out region comprises a second sub-fan-out wire, wherein,
the first sub-fan-out wire is located in at least one of the second metal layer or the third metal layer, and the second sub-fan-out wire is located in the fourth metal layer.

17. An array substrate, comprising: a base substrate, and a plurality of first fan-out wires;
wherein the base substrate comprises a display region and a non-display region, and the display region comprises a corner display region and a middle display region; the corner display region is located between the middle display region and the non-display region; and
the display region comprises a plurality of pixel circuits arranged in an array and a plurality of data signal lines, the plurality of pixel circuits and the plurality of data signal lines are located on one side of the base substrate, a column of pixel circuits of the plurality of pixel circuits are electrically connected to at least two of the plurality of data signal lines, a pixel circuit of the plurality of pixel circuits comprises an N-type transistor and a P-type transistor, the N-type transistor comprises a metal oxide active layer, and the P-type transistor comprises a low-temperature polycrystalline silicon active layer;
wherein a first terminal of a first fan-out wire of the plurality of first fan-out wires is electrically connected to a data signal line located in the corner display region, and a second terminal of the first fan-out wire is located on one side, facing the middle display region, of the data signal line electrically connected to the first terminal of the first fan-out wire; and
wherein the non-display region comprises a fan-out region, and the fan-out region comprises a plurality of second fan-out wires;
a terminal of a second fan-out wire of part of the plurality of second fan-out wires is electrically connected to the second terminal of the first fan-out wire; and
the first fan-out wire and a gate layer of the N-type transistor are disposed in a same layer.

18. A display panel, comprising an array substrate, wherein the array substrate comprises a base substrate, and a plurality of first fan-out wires;
wherein the base substrate comprises a display region and a non-display region, and the display region comprises a corner display region and a middle display region; the corner display region is located between the middle display region and the non-display region; and
the display region comprises a plurality of pixel circuits arranged in an array and a plurality of data signal lines, the plurality of pixel circuits and the plurality of data signal lines are located on one side of the base substrate, a column of pixel circuits of the plurality of pixel circuits are electrically connected to at least two of the plurality of data signal lines, a pixel circuit of the plurality of pixel circuits comprises an N-type transistor and a P-type transistor, the N-type transistor comprises a metal oxide active layer, and the P-type transistor comprises a low-temperature polycrystalline silicon active layer;
wherein a first terminal of a first fan-out wire of the plurality of first fan-out wires is electrically connected to a data signal line located in the corner display region, and a second terminal of the first fan-out wire is located on one side, facing the middle display region, of the data signal line electrically connected to the first terminal of the first fan-out wire; and
wherein the non-display region comprises a fan-out region, and the fan-out region comprises a plurality of second fan-out wires;
a terminal of a second fan-out wire of part of the plurality of second fan-out wires is electrically connected to the second terminal of the first fan-out wire; and
the first fan-out wire and a gate layer of the N-type transistor are disposed in a same layer.

19. A display panel, comprising the array substrate of claim 17.

20. A display device, comprising the display panel of claim 18.
